(19) United States
(12) Patent Application Publication
(10) Pub. No.: US 2026/0231404 A1
(43) Pub. Date: Aug. 6, 2026

(54) SEMICONDUCTOR DEVICE AND MANUFACTURING METHOD OF THE SAME

(71) Applicant: SK hynix Inc., Icheon-si Gyeonggi-do (KR)

(72) Inventor: Nam Jae LEE, Icheon-si Gyeonggi-do (KR)

(73) Assignee: SK hynix Inc., Icheon-si Gyeonggi-do (KR)

(21) Appl. No.: 19/256,935

(22) Filed: Jul. 1, 2025

(30) Foreign Application Priority Data
Jan. 31, 2025 (KR) 10-2025-0012509

(51) Int. Cl. H01L 23/00; H01L 25/065; H01L 25/18; H10B 41/27; H10B 41/35; H10B 43/27; H10B 43/35; H10B 80/00

(52) U.S. Cl. CPC H10B 41/27; H10B 41/35; H10B 43/27; H10B 43/35; H10B 80/00; H10W 72/019; H10W 90/00; H10W 72/923; H10W 72/942; H10W 90/792

(57) ABSTRACT

A semiconductor device and a method of manufacturing the semiconductor device are provided. The semiconductor device includes a plurality of wirings spaced apart by a filled region and an unfilled region between consecutive wirings of the plurality of wirings, an insulating layer arranged in the filled region, and a sealing insulating layer arranged over the unfilled region.

### CROSS-REFERENCE TO RELATED APPLICATION

The present application claims priority under 35 U.S.C. § 119(a) to Korean patent application number 10-2025-0012509 filed on Jan. 31, 2025, in the Korean Intellectual Property Office, the entire contents of which application is incorporated herein by reference.

### BACKGROUND

### 1. Technical Field

The present disclosure relates to a semiconductor device and a method of manufacturing the semiconductor device.

### 2. Related Art

A semiconductor device includes a plurality of wirings for electrical connections. As semiconductor devices become highly integrated, the spacing between the plurality of wirings decreases. The parasitic capacitance increases as the spacing between the wrings decreases.

### SUMMARY

According to an embodiment, a semiconductor device may include a plurality of wirings extending in parallel in in a first plane and spaced apart by a filled region and an unfilled region between consecutive wirings of the plurality of wirings, an insulating layer arranged in the filled region, a conductive pad pattern spaced apart from the plurality of wirings in a first direction perpendicular to the first plane, a conductive contact plug extending between the conductive pad pattern and a corresponding wiring of the plurality of wirings and contacting the corresponding wiring, a capping insulation pattern covering the insulating layer and surrounding the conductive contact plug, and a sealing insulating layer arranged over the plurality of wirings and sealing the unfilled region.

According to an embodiment, a semiconductor device may include a cell array including a plurality of memory cell strings arranged in a plurality of columns in a first plane, a plurality of bit lines extending in a column direction and coupled to the plurality of columns of the plurality of memory cell strings, the plurality of bit lines spaced apart in a row direction by a filled region and an unfilled region between consecutive bit lines of the plurality of bit lines, a sealing insulating layer covering a section of each of the consecutive bit lines, the sealing insulating layer sealing the unfilled region, wherein the unfilled region is located between the sealing insulating layer and the cell array, an insulation structure arranged in the filled region, and a first conductive bonding structure coupled to a corresponding bit line of the plurality of bit lines and arranged not to overlap the unfilled region in a first direction perpendicular to the first plane.

According to an embodiment, a method of manufacturing a semiconductor device may include forming an insulating layer covering a first structure, forming a plurality of wirings extending through the insulating layer and extending in parallel, forming a capping insulation pattern over the plurality of wirings and the insulating layer to partially cover a space between consecutive wirings among the plurality of wirings, removing a section of the insulating layer not covered by the capping insulation pattern, forming a sealing insulating layer covering a region from which the section of the insulating layer is removed such that a cavity is formed in the region, and forming a conductive structure passing through the capping insulation pattern and contacting a corresponding wiring of the plurality of wirings.

### BRIEF DESCRIPTION OF THE DRAWINGS

FIG. 1A, FIG. 1B, and FIG. 1C are diagrams illustrating a semiconductor device according to an embodiment of the present disclosure;

FIG. 2 is a block diagram illustrating an electronic system according to an embodiment of the present disclosure;

FIG. 3 is a block diagram illustrating a semiconductor device according to an embodiment of the present disclosure;

FIG. 4 is a diagram illustrating a cell array and a peripheral circuit of a semiconductor device according to an embodiment of the present disclosure;

FIG. 5 is a cross-sectional view illustrating a semiconductor device according to an embodiment of the present disclosure;

FIG. 6 is a perspective view illustrating an arrangement of bit lines, bit line connection structures, and channel pillars of a semiconductor device according to an embodiment of the present disclosure;

FIG. 7A, FIG. 7B, FIG. 7C, FIG. 7D, and FIG. 7E are cross-sectional views of a semiconductor device formed, prior to a bonding process, by utilizing a method of manufacturing a semiconductor device according to an embodiment of the present disclosure; and

FIG. 8A and FIG. 8B are cross-sectional views of a semiconductor device formed, after a bonding process, by utilizing a method of manufacturing a semiconductor device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

Terms such as “first” and “second” are used to distinguish between various elements and do not imply size, order, priority, quantity, or importance of the elements. For example, a first element may be referred to as a second element in one example, and the second element may be referred to as a first element in another example. Terms such as “vertical,” “top,” “bottom,” “over,” “overlap,” “on,” “side,” “upper,” “uppermost,” “lower,” “higher,” “high,” “low,” “column,” “row,” “level,” and other terms implying relative spatial relationship or orientation are utilized only for the purpose of ease of description or reference to a drawing and are not otherwise limiting. When one element is identified as “coupled” to another element, the elements may be coupled directly or through at least one intervening element between the elements. When two elements are identified as “directly coupled,” one element is directly coupled to the other element without an intervening element between the two elements. The cross-hatching throughout the figures illustrates corresponding or similar regions between the figures rather than indicating the materials for the regions.

Semiconductor devices are described that reduce parasitic capacitance to improve the operational reliability of the semiconductor devices. To reduce the parasitic capacitance, a cavity such as an air-gap is arranged between wirings. The cavity may cause process defects. One or more embodiments include a semiconductor device and a method of manufacturing the semiconductor device with improved operational reliability and reduced process defects.

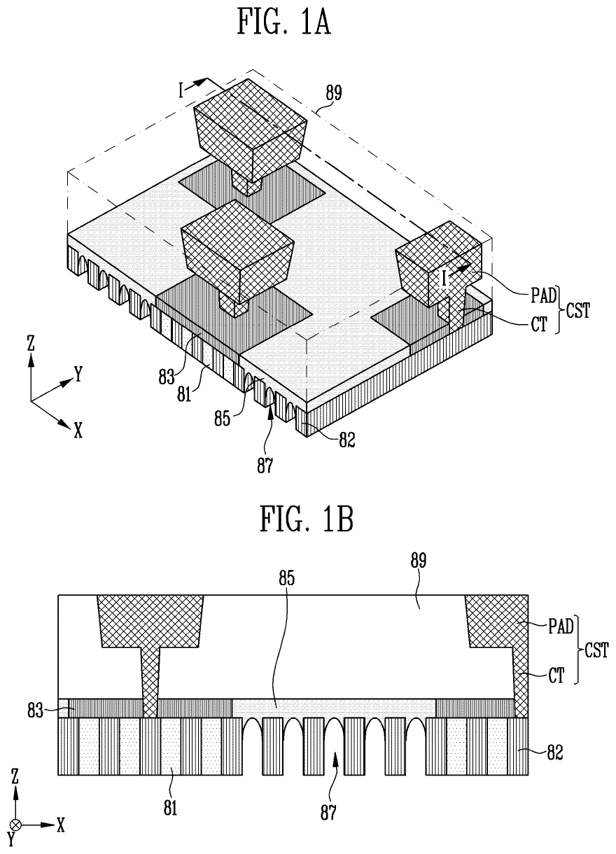

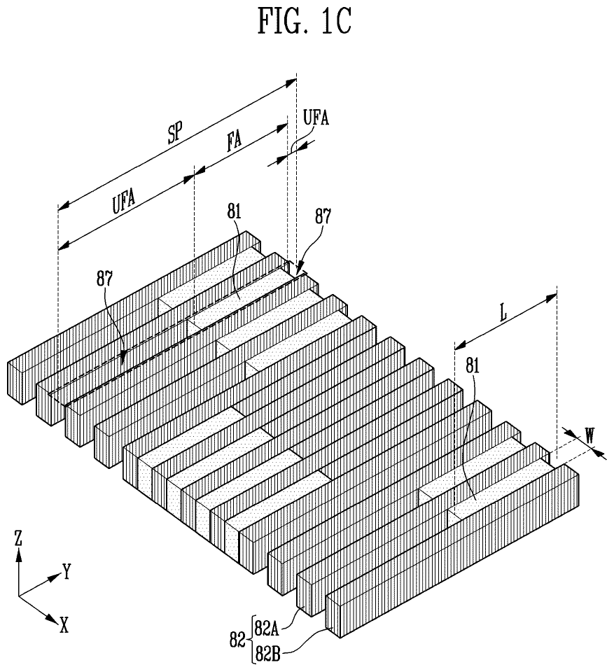

FIG. 1A, FIG. 1B, and FIG. 1C are diagrams illustrating a semiconductor device according to an embodiment of the present disclosure. FIG. 1A is a perspective view of a section of a semiconductor device. FIG. 1B is a cross-sectional view of the semiconductor device taken along line I-I′ in FIG. 1A. FIG. 1C is a perspective view showing some of the components of FIG. 1A.

Referring to FIG. 1A, FIG. 1B, and FIG. 1C, the semiconductor device includes a plurality of wirings 82, an insulating layer 81, a plurality of capping insulation patterns 83, a sealing insulating layer 85, an insulation structure 89, and a plurality of conductive structures CST.

The plurality of wirings 82 are electrically coupled to a structure including a circuit pattern (not shown), and may include various conductive materials. The circuit pattern includes a passive element such as a resistor, a capacitor, or the like, a logic circuit including a plurality of transistors, a memory circuit including a plurality of memory cells, or a combination of passive elements, logic circuits, and memory circuits.

Referring to FIG. 1A and FIG. 1B, the plurality of conductive structures CST is coupled to the plurality of wirings 82. For example, each of the plurality of conductive structures CST is coupled to a corresponding one of the plurality of wirings 82. FIG. 1A and FIG. 1B show a subset of the plurality of wirings 82 and a subset of the plurality of conductive structures CST.

Referring to FIG. 1C, the plurality of wirings 82 extend in parallel in an XY plane and are spaced apart by a space SP having a non-filled or unfilled region UFA and a filled region FA between consecutive wirings 82. In an embodiment, the plurality of wirings 82 extends in a Y direction and is spaced apart in an X direction.

The insulating layer 81 or an insulation structure, referred to as an insulator, is arranged in the filled region FA. The insulating layer 81 is not located inside the unfilled region UFA, and the unfilled region UFA is referred to as a cavity 87. The cavity 87 is an air-gap. Accordingly, the insulating layer 81 and the cavity 87 are arranged in the space SP between consecutive wirings of the plurality of wirings 82. A separation distance between consecutive wirings of the plurality of wirings 82 is maintained using the insulating layer 81 as a support structure, and the parasitic capacitance between the plurality of wirings 82 may be reduced due to the cavity 87.

The insulating layer 81 is formed in a bar shape to provide support. In an embodiment, the plurality of wirings 82 includes consecutive wirings 82A and 82B. The insulating layer 81 has a width W corresponding to the separation distance between the consecutive wirings 82A and 82B and a length L formed in a direction parallel to the consecutive wirings 82A and 82B. Because the length L of the insulating layer 81 is greater than the width W, the insulating layer 81 is formed in a bar shape.

Referring to FIG. 1A, FIG. 1B, and FIG. 1C, the cavity 87 is formed when the sealing insulating layer 85 is formed over the plurality of wirings 82 such that the unfilled area UFA is sealed. The sealing insulating layer 85 may include a material capable of preventing metal diffusion. In an embodiment, the sealing insulating layer 85 may include nitrogen-doped silicon carbide.

Referring to FIG. 1A and FIG. 1B, the sealing insulating layer 85 surrounds each of the plurality of capping insulation patterns 83. The sealing insulating layer 85 may is disposed around the plurality of capping insulation patterns 83. Each of the plurality of capping insulation patterns 83 is associated with one of the plurality of conductive structures CST.

The insulation structure 89 is arranged over the plurality of capping insulation patterns 83 and the sealing insulating layer 85 to cover the plurality of capping insulation patterns 83 and the sealing insulating layer 85. The insulation structure 89 includes a single-layer insulating layer or two or more insulating layers.

Each of the plurality of conductive structures CST includes a region arranged within a corresponding capping insulation pattern 83 and a region arranged in the insulation structure 89. Each of the plurality of conductive structures CST contacts with a corresponding wiring 82. Each of the plurality of conductive structures CST includes an end adjacent to a corresponding wiring 82, and the end is surrounded by a corresponding capping insulation pattern 83.

In an embodiment, each of the plurality of conductive structures CST includes a conductive contact plug CT and a conductive pad pattern PAD. The conductive pad pattern PAD is spaced apart from the plurality of wirings 82 and the capping insulation pattern 83 in a vertical direction, such as a Z direction perpendicular to the XY plane. The insulation structure 89 is interposed between the conductive pad pattern PAD and the capping insulation pattern 83. The conductive pad pattern PAD may have a greater width than a corresponding wiring 82. The conductive contact plug CT extends between the conductive pad pattern PAD and the corresponding wiring 82 and contacts the corresponding wiring 82. The conductive contact plug CT has a smaller width than the conductive pad pattern PAD. An end of the conductive contact plug CT is an end of the conductive structure CST surrounded by the capping insulation pattern 83. Each of the conductive pad pattern PAD and the capping insulation pattern 83 have a greater width than the conductive contact plug CT in this example.

The conductive contact plug CT and the conductive pad pattern PAD form an integral conductive structure CST. The conductive structure CST may include a metal capable of bonding and form a bonding structure. In an embodiment, the conductive contact plug CT and the conductive pad pattern PAD of the conductive structure CST may include copper, aluminum, or tungsten. The conductive structure CST may further include a seed layer or a barrier layer that forms an interface with each of the insulation structures 89, the capping insulation pattern 83, and the corresponding wiring 82. In one embodiment, the seed layer or the barrier layer may include a single layer of titanium or titanium nitride, or a double layer of titanium/titanium nitride.

The insulation structure 89 surrounds an upper section of the conductive contact plug CT projecting in a vertical direction relative to the capping insulation pattern 83 and surrounds a sidewall of the conductive pad pattern PAD.

The capping insulation pattern 83 is located over the insulating layer 81 around a contact surface between the conductive structure CST and the corresponding wiring 82. The capping insulation pattern 83 extends to cover a section of the corresponding wiring 82 around the contact surface between the corresponding conductive structure CST and the corresponding wiring 82. The capping insulation pattern 83 has a greater width than the wiring 82. In an embodiment, the capping insulation pattern 83 extends to cover at least one wiring adjacent to a corresponding one of the plurality of wirings 82.

The insulating layer 81 includes a material having an etch selectivity relative to an etch selectivity of the capping insulation pattern 83. In an embodiment, the insulating layer 81 may include silicon oxide, and the capping insulation pattern 83 may include silicon nitride.

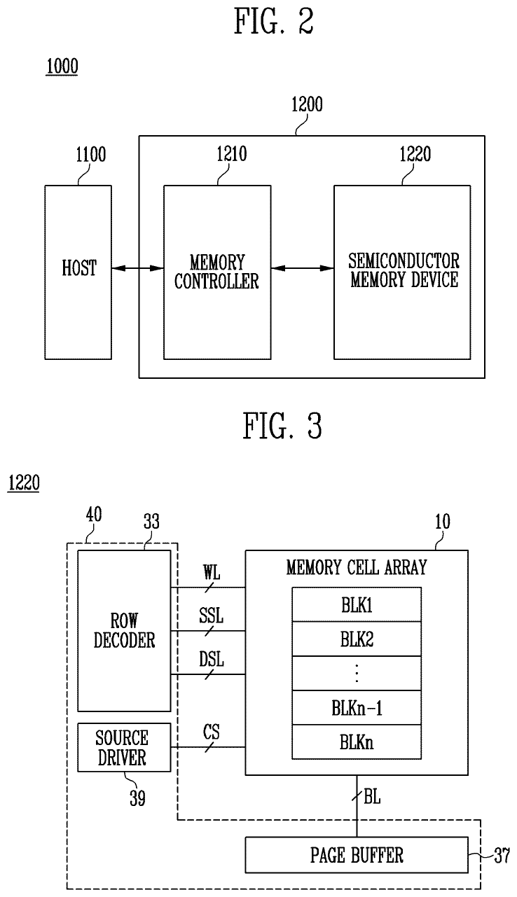

FIG. 2 is a block diagram illustrating an electronic system 1000 according to an embodiment of the present disclosure.

Referring to FIG. 2, the electronic system 1000 includes the components of the semiconductor device as described with reference to FIG. 1A, FIG. 1B, and FIG. 1C. The electronic system 1000 may be a computing system, a medical device, a communication device, a wearable device, a memory system, or the like. The electronic system 1000 includes a host 1100 and a storage device 1200.

The host 1100 stores data in the storage device 1200 or reads data stored in the storage device 1200 based on an interface. The interface may include one or more of a Double Data Rate (DDR) interface, a Universal Serial Bus (USB) interface, a multimedia card (MC) interface, an embedded MMC (eMMC) interface, a peripheral component interconnection (PCI) interface, a PCI-express (PCI-E) interface, an Advanced Technology Attachment (ATA) interface, a Serial-ATA interface, a Parallel-ATA interfaces, a small computer system interface (SCSI), an enhanced small disk interface (ESDI), an Integrated Drive Electronics (IDE) interface, a Firewire interface, a Universal Flash Storage (UFS) interface, and a Nonvolatile Memory express (NVMe) interface.

The storage device 1200 includes a memory controller 1210 and a semiconductor memory device 1220. In an embodiment, the storage device 1200 may be a storage medium such as a solid-state drive (SSD), a Universal Serial Bus (USB) memory, or the like.

The host 1100 controls the memory controller 1210 to store data in the semiconductor memory device 1220 or to read data stored in the semiconductor memory devices 1220.

The semiconductor memory device 1220 includes one memory chip or a plurality of memory chips. The semiconductor memory device 1220 stores data or outputs stored data in response to control of the memory controller 1210.

The semiconductor memory device 1220 includes the components of the semiconductor device as described with reference to FIG. 1A, FIG. 1B, and FIG. 1C. The semiconductor memory device 1220 may be a non-volatile memory device. The semiconductor memory device 1220 includes a cell array and a peripheral circuit that control operation of the cell array structure. The cell array includes a plurality of memory cells. Each of the memory cells may be a non-volatile memory cell. In an embodiment, each memory cell is configured as a NAND flash memory cell, a ferroelectric memory cell, a variable resistance memory cell, or the like. The plurality of wirings 82 as described with reference to FIG. 1A, FIG. 1B, and FIG. 1C are coupled to the peripheral circuit or coupled to the cell array.

FIG. 3 is a block diagram illustrating a semiconductor device according to an embodiment of the present disclosure.

Referring to FIG. 3, the semiconductor device is the semiconductor memory device 1220 in this example. The semiconductor memory device 1220 includes a peripheral circuit 40 and a memory cell array 10. In an embodiment, the peripheral circuit 40 and the memory cell array 10 may implement a NAND flash memory device. The present disclosure is described based on the peripheral circuit 40 and the memory cell array 10 of a NAND flash memory device, although the present disclosure is not limited to this example.

The peripheral circuit 40 performs a program operation to store data in the memory cell array 10, a read operation to output data stored in the memory cell array 10, and an erase operation to erase data stored in the memory cell array 10. In an embodiment, the peripheral circuit 40 includes a row decoder 33, a page buffer 37, and a source driver 39.

The peripheral circuit 40 is coupled to the memory cell array 10 using a plurality of common source structures or source lines CS, a plurality of bit lines BL, a plurality of drain select lines DSL, a plurality of word lines WL, and a plurality of source select lines SSL.

The row decoder 33 transfers operating voltages to the plurality of drain select lines DSL, the plurality of word lines WL, and the plurality of source select lines SSL.

The page buffer 37 may store data for a program operation. During the program operation, the page buffer 37 may apply voltages to the plurality of bit lines BL based on data stored in the page buffer 37. During a read operation, the page buffer 37 senses voltages or currents of the plurality of bit lines BL and stores the sensed result.

The source driver 39 controls a voltage or a bias applied to each of the plurality of source lines CS or grounds each of the plurality of source lines CS.

The memory cell array 10 includes a plurality of memory blocks BLK1 to BLKn, where n is an integer greater than or equal to 2. The plurality of memory blocks BLK1 to BLKn are coupled to the page buffer 37 via the plurality of bit lines BL. An erase operation is controlled using the source line CS to the memory block. At least one source layer is coupled to the source line CS.

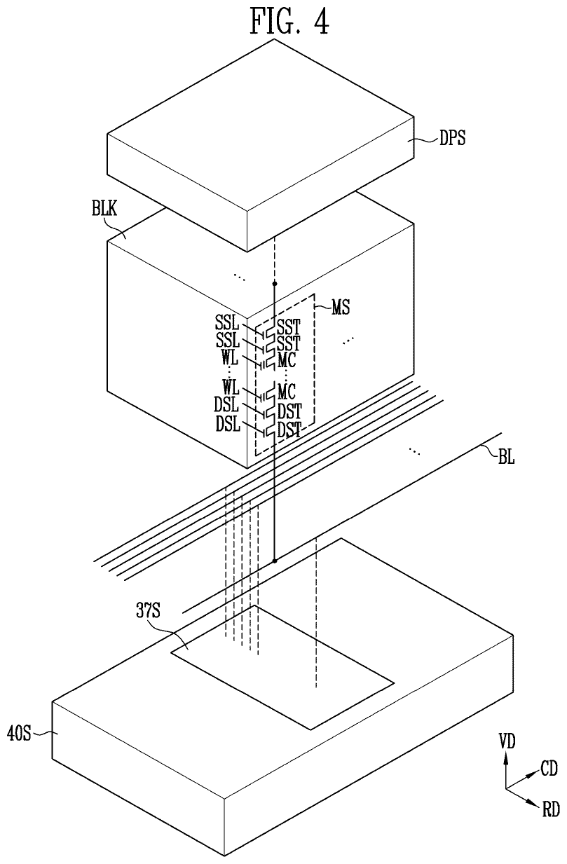

FIG. 4 is a diagram illustrating a cell array and a peripheral circuit of a semiconductor device according to an embodiment of the present disclosure.

Referring to FIG. 4, the semiconductor device is a semiconductor memory device. A memory block BLK of the cell array includes a plurality of memory cells MC arranged in three dimensions. By arranging the plurality of memory cells MC in three dimensions, a degree of integration of memory cells in a limited area may be improved.

In an embodiment, each memory cell MC is a NAND flash memory cell. In a NAND flash memory device, the plurality of memory cells MC are included in a plurality of memory cell strings MS. The plurality of memory cell strings MS are arranged in a plurality of rows and a plurality of columns in the XY plane. Each of the plurality of rows includes the memory cell strings MS arranged in line in a row direction RD, such as the X direction, and each of the plurality of columns includes the memory cell strings MS arranged in a column direction CD, such as the Y direction.

The plurality of memory cell strings MS are coupled to the plurality of bit lines BL, a doped semiconductor structure DPS, and a plurality of gate conductive layers DSL, WL, and SSL. The plurality of bit lines BL extend in the column direction CD to be respectively coupled to a plurality of columns of the plurality of memory cell strings MS. The memory cell strings MS in different columns are coupled to different bit lines BL. The doped semiconductor structure DPS is spaced apart from the plurality of bit lines BL in a vertical direction VD perpendicular to the XY plane. Each of the plurality of memory cell strings MS is arranged between the doped semiconductor structure DPS and one of the plurality of bit lines BL.

The plurality of gate conductive layers DSL, WL, and SSL are arranged between the doped semiconductor structure DPS and the plurality of bit lines BL. The plurality of gate conductive layers DSL, WL, and SSL include at least one drain select line DSL, the plurality of word lines WL, and at least one source select line SSL spaced apart in the vertical direction VD. At least one drain select line DSL is arranged between the plurality of bit lines BL and the plurality of word lines WL. In an embodiment, two drain select lines DSL are arranged between the plurality of bit lines BL and the plurality of word lines WL. At least one source select line SSL is arranged between the doped semiconductor structure DPS and the plurality of word lines WL. In an embodiment, two source select lines SSL are arranged between the doped semiconductor structure DPS and the plurality of word lines WL. The memory cell string MS includes a drain select transistor DST, the plurality of memory cells MC, and a source select transistor SST in this example. A gate of a drain select transistor DST is coupled to the drain select line DSL, gates of the plurality of memory cells MC are respectively coupled to the plurality of word lines WL, and a gate of the source select transistor SST is coupled to the source select line SSL. The drain select transistor DST, the plurality of memory cells MC, and the source select transistor SST are coupled in series through a channel pillar. The channel pillar is electrically coupled to the doped semiconductor structure DPS and a corresponding one of the plurality of bit lines BL and may include a semiconductor material.

A peripheral circuit 40S includes a plurality of transistors and passive elements, such as a resistor and a capacitor, that are included in the peripheral circuit 40 such as shown in FIG. 3. Some regions of the peripheral circuit 40S overlap the cell array including memory block BLK in the vertical direction VD. Accordingly, the arrangement efficiency of the cell array and the peripheral circuit 40S may be improved in a limited region.

The peripheral circuit 40S is electrically coupled to the memory block BLK via conductive structures and interconnections made of a conductive material. In an embodiment, the plurality of bit lines BL is arranged closer to the peripheral circuit 40S than to the doped semiconductor structure DPS and is electrically coupled to the transistors constituting a page buffer structure 37S of the peripheral circuit 70S via interconnections and conductive structures. The conductive structures include a plurality of first conductive bonding structures bonded to a plurality of second conductive bonding structures. The plurality of bit lines BL and the plurality of first conductive bonding structures include the plurality of wirings 82 and the plurality of conductive structures CST such as shown in FIG. 1A, FIG. 1B, and FIG. 1C. Alternatively, the plurality of second conductive bonding structures and top layer patterns of the interconnections include the plurality of wirings 82 and the plurality of conductive structures CST such as shown in FIG. 1A, FIG. 1B, and FIG. 1C.

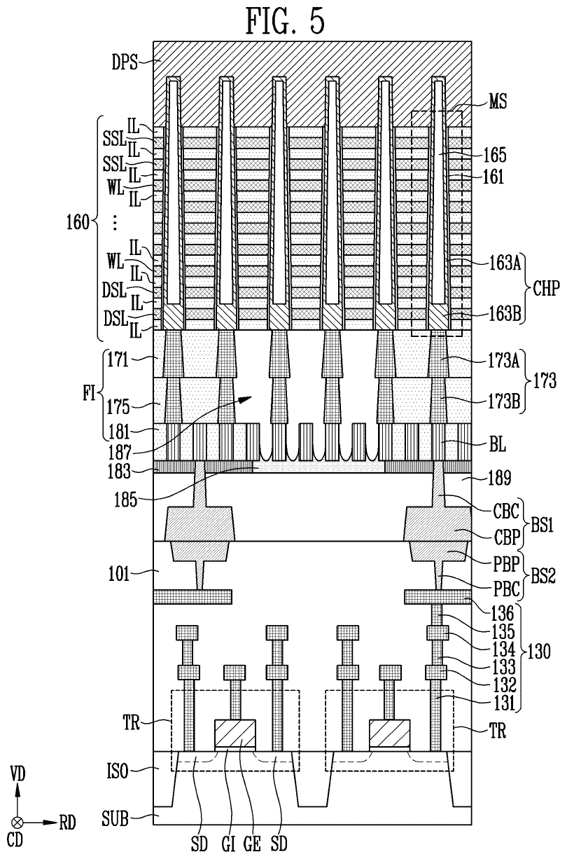

FIG. 5 is a cross-sectional view illustrating a semiconductor device according to an embodiment of the present disclosure.

Referring to FIG. 5, the semiconductor device is a semiconductor memory device. The cell array of the semiconductor memory device includes the plurality of memory cell strings MS arranged in the row direction RD and the column direction CD in the XY plane. The plurality of memory cell strings MS overlaps the peripheral circuit in the vertical direction VD that is perpendicular to the XY plane. The peripheral circuit of the semiconductor memory device includes transistors TR. The transistors TR are arranged in active regions of a semiconductor substrate SUB within an isolation layer ISO.

The semiconductor substrate SUB includes a semiconductor material. In an embodiment, the semiconductor material may include one or more of a group IV semiconductor, a group III-V compound semiconductor, and a group II-VI compound semiconductor. The group IV semiconductors include single crystal silicon (Si), polycrystalline silicon, germanium (Ge), or silicon germanium (SiGe). The group III-V compound semiconductors include GaAs, GaN, GaP, GaAsP, GaInAsP, AlAs, AlGa, InP, InSb, or InGaAs. The group II-VI compound semiconductors include ZnS, ZnO, or CdS.

The semiconductor substrate SUB included a dielectric layer. In an embodiment, the semiconductor substrate SUB may be a silicon-on-insulator (SOI) substrate or a germanium-on-insulator (GeOI) substrate. The semiconductor substrate SUB may include an organic material. In an embodiment, the semiconductor substrate SUB may include graphene.

The semiconductor substrate SUB may be a bulk wafer or an epitaxial layer grown through a selective epitaxial growth (SEG) manner. Alternatively, the semiconductor substrate SUB may be a layer formed through a Metal Induced Lateral Crystallization (MILC) method and may partially include a metal.

The semiconductor substrate SUB may be in a single crystal, polycrystalline or amorphous state. The semiconductor substrate SUB may include impurities of Group II, III, IV, V or VI. In an embodiment, the semiconductor substrate SUB includes an n-well region doped with n-type impurities, a p-well region doped with p-type impurities, or both an n-well region and a p-well region.

The semiconductor substrate SUB includes an active region partitioned by the isolation layer ISO. Each of the plurality of transistors TR includes a gate insulating layer GI, a gate electrode GE, and source/drain regions SD. The gate insulating layer GI and the gate electrode GE are stacked over the active region. A source/drain regions SD is located in the active region on each side of the gate electrode GE. The active region between the source/drain regions SD functions as a channel region. Each of the source/drain regions SD includes conductive impurities that function as a source region or a drain region of the transistor TR. Majority carriers of the source/drain regions SD include n-type impurities or p-type impurities depending on the electrical characteristics of the transistor TR. In an embodiment, the source/drain regions SD of a p-channel metal oxide semiconductor (PMOS) transistor include p-type impurities as majority carriers. In an embodiment, the source/drain regions SD of an n-channel metal oxide semiconductor (NMOS) transistor include n-type impurities as majority carriers.

In an embodiment, the plurality of transistors TR are included in the page buffer structure 37S such as described with reference to FIG. 4.

The plurality of transistors TR and the isolation layer ISO are covered with a peripheral circuit-side insulation structure 101. The peripheral circuit-side insulation structure 101 may include multiple insulating layers.

The plurality of memory cell strings MS include a plurality of columns. The plurality of memory cell strings MS includes a plurality of channel pillars CHP, and each of the plurality of memory cell strings MS is formed along a corresponding channel pillar CHP. Each of the plurality of channel pillars CHP extends in the vertical direction VD.

Each of the plurality of channel pillars CHP includes a channel layer 163A. The channel layer 163A includes a semiconductor material, such as silicon (Si), germanium (Ge), or a combination thereof, which may be a channel region of a corresponding memory cell string MS. The channel layer 163A may have a tubular structure. The channel pillar CHP includes a capping pattern 163B and a core insulating layer 165 arranged in a central region of the tubular structure including the channel layer 163A. The capping pattern 163B may include a semiconductor layer doped with conductive impurities. The conductive impurities may include n-type impurities, or both n-type impurities and p-type impurities. In an embodiment, the capping pattern 163B may include n-type doped silicon that includes n-type impurities as majority carriers.

The plurality of channel pillars CHP are surrounded by the plurality of gate conductive layers DSL, WL, and SSL of a gate stack 160. The plurality of gate conductive layers DSL, WL, and SSL are spaced apart in the vertical direction VD. Each of the plurality of gate conductive layers DSL, WL, and SSL may include various conductive materials such as a doped semiconductor layer and a metal layer. The doped semiconductor layer may include a doped silicon layer. The metal layer may include tungsten, copper, molybdenum, or the like. Each of the plurality of gate conductive layers DSL, WL, and SSL may further include a metal barrier layer. The metal barrier layer may include a metal nitride layer, and the metal nitride layer may include titanium nitride, tantalum nitride, or the like. In an embodiment, the metal barrier layer may include a double layer of titanium and titanium nitride. The plurality of gate conductive layers DSL, WL, and SSL includes at least one drain select line DSL, at least one source select line SSL, and the plurality of word lines WL arranged between the drain select line DSL and the source select line SSL.

The gate stack 160 includes the plurality of gate conductive layers DSL, WL, and SSL alternately stacked with a plurality of interlayer insulating layers IL in the vertical direction VD. Each of the plurality of gate conductive layers DSL, WL, and SSL is interposed between consecutive interlayer insulating layers IL in the vertical direction VD. Each of the plurality of interlayer insulating layers IL may include an insulating material such as a silicon oxide layer or a silicon oxynitride layer.

A memory layer 161 is interposed between each of the plurality of channel pillars CHP and the gate stack 160. The memory layer 161 surrounds a sidewall of the channel pillar CHP. The memory layer 161 includes a tunnel insulating layer, a data storage layer, and a blocking insulating layer. Though not shown in FIG. 5, the tunnel insulating layer is interposed between the channel pillar CHP and the gate stack 160, the data storage layer is interposed between the tunnel insulating layer and the gate stack 260, and the blocking insulating layer is interposed between the data storage layer and the gate stacked body 160 in this example. The tunnel insulating layer may include an oxide such as silicon dioxide (SiO₂). The data storage layer may include a material layer capable of storing data that is changed using Fowler-Nordheim tunneling. In an embodiment, the data storage layer may include a charge trap layer, or an insulating layer including conductive nanodots. The charge trap layer may include a silicon nitride layer. In an embodiment, the data storage layer may include a floating gate. When the data storage layer includes a charge trap layer or an insulating layer including conductive nanodots, the data storage layer continuously extends in the vertical direction VD on a sidewall of each of the plurality of gate conductive layers DSL, WL, and SSL and the plurality of interlayer insulating layers IL. When the data storage layer includes a charge trap layer, an insulating layer including conductive nanodots, or a floating gate, the data storage layer may be separated into a plurality of data storage patterns spaced apart in the vertical direction VD. A plurality of data storage patterns is arranged at levels where the plurality of gate conductive layers DSL, WL, and SSL are arranged. The blocking insulating layer may include an oxide such as silicon dioxide (SiO₂), a high-dielectric insulating material having a higher dielectric constant than silicon dioxide, or the like. The high-dielectric insulating material may include an aluminum oxide layer, a hafnium oxide layer, or the like.

A source select transistor is formed at an intersection of the source select line SSL and the channel layer 163A, a drain select line is formed at an intersection of the drain select line DSL and the channel layer 163A, and a plurality of memory cells is formed at intersections of the plurality of word lines WL and the channel layer 163A. The source select transistor, the plurality of memory cells, and the drain select transistor are coupled in series by the channel layer 163A of the channel pillar CHP to form the memory cell string MS.

The plurality of channel pillars CHP and the gate stack 160 are arranged between the doped semiconductor structure DPS and the plurality of bit lines BL. The plurality of bit lines BL are arranged between the peripheral circuit-side insulation structure 101 and the gate stack 60.

The plurality of bit lines BL extends in the column direction CD and couples to a plurality of columns of the plurality of channel pillars CHP. The plurality of bit lines BL is spaced apart in the row direction RD. The plurality of bit lines BL may be directly coupled to the plurality of channel pillars CHP or may be coupled to the plurality of channel pillars CHP via a plurality of bit line connection structures 173.

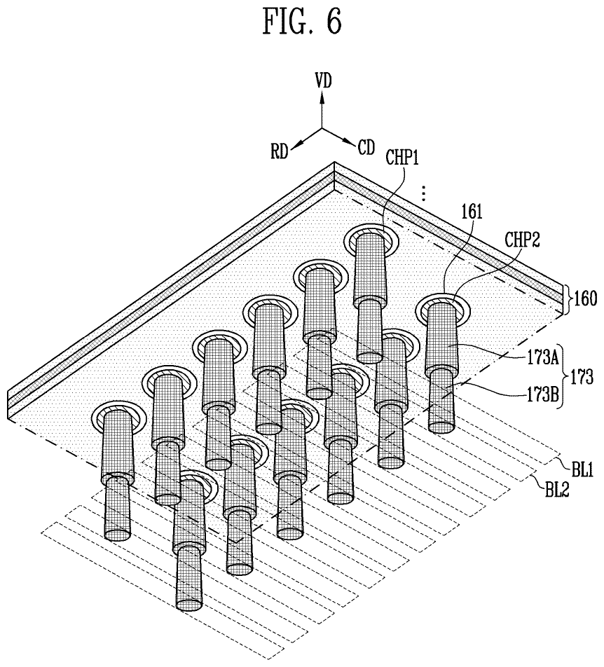

FIG. 6 is a perspective view illustrating arrangements of bit lines, bit line connection structures, and channel pillars of a semiconductor device according to an embodiment of the present disclosure.

Referring to FIG. 5 and FIG. 6, each of the plurality of bit line connection structures 173 are arranged between the gate stack 160 and one of the plurality of bit lines BL and overlaps one of a plurality of channel pillars CHP in the vertical direction VD.

The plurality of channel pillars CHP may be arranged in a zigzag, offset, or angled pattern in the row direction RD and the column direction CD. The plurality of channel pillars CHP includes a first channel pillar CHP1 and a second channel pillar CHP2 arranged in consecutive columns. The first channel pillar CHP1 and the second channel pillar CHP2 are coupled to a first bit line BL1 a second bit line BL2, respectively, among the plurality of bit lines BL. Each of the plurality of bit line connection structures 173 is arranged between a corresponding bit line BL and a corresponding channel pillar CHP and electrically connects a bit line BL to the corresponding channel pillar CHP.

In an embodiment, each of the plurality of bit line connection structures 173 includes a first conductive contact plug 173A and a second conductive contact plug 173B. The first conductive contact plug 173A contacts a corresponding channel pillar CHP and extends between the channel pillar CHP and a corresponding bit line BL. The second conductive contact plug 173B contacts the first conductive contact plug 173 and contacts the corresponding bit line BL.

Referring to FIG. 5, similar to the plurality of wirings 82 as described with reference to FIG. 1A, FIG. 1B, and FIG. 1C, the plurality of bit lines BL are spaced apart by a space including a filled region and a non-filled or unfilled region between consecutive bit lines BL. As described with reference to FIG. 1A, FIG. 1B, and FIG. 1C, a sealing insulating layer 185, shown in FIG. 5, extends to cover a subset of the bit lines BL with the unfilled region therebetween to seal the unfilled region. As a result, such as shown in FIG. 5, a cavity 187 is located in the unfilled region. The cavity 187 as formed is located between the sealing insulating layer 185 and the gate stack 160 including the cell array. As described with reference to FIG. 1A, FIG. 1B, and FIG. 1C, an insulation structure FI, shown in FIG. 5, is formed in the filled region.

The cavity 187 and the insulation structure FI extend between the plurality of bit line connection structures 173. The parasitic capacitance between consecutive bit lines BL may be reduced due to the cavity 187, and the parasitic capacitance between consecutive bit line connection structures 173 may be reduced due to the cavity 187.

The insulation structure FI includes a first insulating layer 171, a second insulating layer 175, and a third insulating layer 181. The first insulating layer 171 partially fills a space between consecutive first conductive contact plugs 173A of the plurality of bit line connection structures 173. The second insulating layer 175 partially fills the space between consecutive second conductive contact plugs 173B of the plurality of bit line connection structures 173. The plurality of bit lines BL is supported by the first insulating layer 171, the second insulating layer 175, and the plurality of bit line connection structures 173. The third insulating layer 181 fills a filled region in a space between consecutive bit lines BL. Similar to the insulating layer 81 described with reference to FIG. 1C, the third insulating layer 181 of the insulation structure FI has a width corresponding to a separation distance between consecutive bit lines BL and a length in a direction parallel to the plurality of bit lines BL and is formed in a bar shape with a length greater than the width. The third insulating layer 181 is formed in a bar shape with a length in the column direction CD longer than a width in the row direction RD.

Surfaces of the plurality of bit lines BL and the third insulating layer 181 opposite to the gate stack 160 are covered with the sealing insulating layer 185 and a plurality of capping insulation patterns 183. A cell-side insulation structure 189 is arranged between the peripheral circuit-side insulation structure 101 and the sealing insulating layer 185 and between the peripheral circuit-side insulation structure 101 and the plurality of capping insulation patterns 183. The cell-side insulation structure 189 may include a single-layer insulating layer or multiple insulating layers including two or more layers stacked in the vertical direction VD.

A plurality of first conductive bonding structures BS1 is arranged within the cell-side insulation structure 189. The plurality of first conductive bonding structures BS1 corresponds to the plurality of capping insulation patterns 183. Each of the plurality of first conductive bonding structures BS1 contacts a corresponding one of the plurality of bit lines BL via a corresponding capping insulation pattern 183.

Each of the plurality of capping insulation patterns 183 surrounds an end of the corresponding first conductive bonding structure BS1. The end of the first conductive bonding structure BS1 is adjacent to the corresponding bit line BL. Each of the plurality of capping insulation patterns 183 extends around the end of the corresponding first conductive bonding structure BS1 to cover a segment of the corresponding bit line BL and the third insulating layer 181 of the insulation structure FI. Each of the plurality of capping insulation patterns 183 may have a width greater than each of the plurality of bit lines BL. In an embodiment, the capping insulation pattern 183 extend to cover at least two consecutive bit lines BL.

Each of the plurality of first conductive bonding structures BS1 includes a cell-side conductive contact plug CBC and a cell-side conductive pad pattern CBP. An end of the cell-side conductive contact plug CBC forms an end of the first conductive bonding structure BS1 adjacent to the corresponding bit line BL. The cell-side conductive contact plug CBC contacts the corresponding bit line BL and extends away from the cell array. The cell-side conductive contact plugs CBC include a region surrounded by a corresponding capping insulation pattern 183 and a region surrounded by the cell-side insulation structure 189. The cell-side conductive pad pattern CBP extends parallel to the XY plane from the cell-side conductive contact plug CBC such that the cell-side conductive pad pattern CBP has a greater width than the cell-side conductive contact plug CBC. The cell-side conductive pad pattern CBP is spaced apart from the capping insulation pattern 183 in the vertical direction VD and is surrounded by the cell-side insulation structure 189. The cell-side insulation structure 189 is between the capping insulation pattern 183 and the cell-side conductive pad pattern CBP.

The cell-side conductive contact plug CBC and the cell-side conductive pad pattern CBP of the first conductive bonding structure BS1 are arranged not to overlap the cavity 187 in the vertical direction VD. Accordingly, during an etch process including forming a groove in which the first conductive bonding structure BS1 is arranged, a process of forming the cavity 187 may be improved. For example, during the etch process when the cavity 187 is formed, a bit line corresponding to the groove and a bit line not corresponding to the groove are exposed and a misaligned first conductive bonding structure is arranged in the groove. The misaligned first conductive bonding structure may cause a bridge failure connecting different bit lines. According to an embodiment of the present disclosure, forming the cavity 187 during etch process may be avoided. Therefore, the degree of alignment of the first conductive bonding structure BS1 may be increased and bridge failure may be reduced. The capping insulation pattern 183 may function as an etch stop layer during the etch process as described.

Each of the cell-side conductive pad pattern CBP and the capping insulation pattern 183 has a greater width than the cell-side conductive contact plug CBC. The cell-side conductive pad pattern CBP and the cell-side conductive contact plug CBC form an integral first conductive bonding structure BS1.

The first conductive bonding structure BS1 corresponds to the conductive structure CST as described with reference to FIG. 1A and FIG. 1B, the capping insulation pattern 183 and the sealing insulating layer 185 correspond to the capping insulation pattern 83 and the sealing insulating layer 85 as described with reference to FIG. 1A and FIG. 1B, respectively, and the third insulating layer 181 of the cell-side insulation structure 189 and the insulation structure FI correspond to the insulation structure 89 and the insulating layer 81 as described with reference to FIG. 1A and FIG. 1B, respectively. For example, the materials of the first conductive bonding structure BS1, the capping insulation pattern 183, the sealing insulating layer 185, the cell-side insulation structure 189, and the third insulating layer 181 may be similar to the materials of the conductive structure CST, the capping insulation patterns 83, the sealing insulating layers 85, the insulation structure 89, and the insulating layers 81 as described with reference to FIG. 1A and FIG. 1B.

The first insulating layer 171 and the second insulating layer 175 of the insulation structure FI may include a material having an etch selectivity relative to the capping insulation pattern 183. In an embodiment, the first insulating layer 171 and the second insulating layer 175 include similar materials as the third insulating layer 181.

Each of the plurality of first conductive bonding structures BS1 is bonded to a corresponding one of the plurality of second conductive bonding structures BS2. Each of the plurality of second conductive bonding structures BS2 is electrically coupled to one of the plurality of transistors TR of the peripheral circuit via interconnections 130.

The interconnections 130 include conductive patterns 131, 132, 133, 134, 135, and 136 arranged in the peripheral circuit-side insulation structure 101. The conductive patterns 131, 132, 133, 134, 135, and 136 are coupled to the gate electrode GE and the source/drain regions S/D of each of the plurality of transistors TR.

Each of the plurality of second conductive bonding structures BS2 contacts the uppermost conductive pattern 136 of a corresponding one of the interconnections 130 and contacts the corresponding first conductive bonding structure BS1. The plurality of second conductive bonding structures BS2 are arranged in the peripheral circuit-side insulation structure 101. Each of the plurality of second conductive bonding structures BS2 includes a peripheral circuit-side conductive contact plug PBC and a peripheral circuit-side conductive pad pattern PBP. The peripheral circuit-side conductive contact plug PBC contacts the uppermost conductive pattern 136 and extends in the vertical direction VD between the plurality of transistors TR and the peripheral circuit-side conductive pad pattern PBP. The peripheral circuit-side conductive pad pattern PBP extends between the peripheral circuit-side conductive contact plug PBC and the cell-side conductive pad pattern CBP and is bonded to the cell-side conductive pad pattern CBP. The peripheral circuit-side conductive pad pattern PBP has a greater width than the peripheral circuit-side conductive contact plug PBC.

The peripheral circuit-side conductive pad pattern PBP and the peripheral circuit-side conductive contact plug PBC form an integral second conductive bonding structure BS2. The second conductive bonding structure BS2 includes a metal that can be bonded. In an embodiment, the peripheral circuit-side conductive pad pattern PBP and the peripheral circuit-side conductive contact plug PBC of the second conductive bonding structure BS2 may include copper, aluminum, or tungsten. The second conductive bonding structure BS2 may include a seed layer or a barrier layer that forms an interface with the peripheral circuit-side insulation structure 101. In an embodiment, the seed layer or the barrier layer may include a single layer of titanium, titanium nitride, or a double layer of titanium/titanium nitride.

Some or all of the doped semiconductor structure DPS functions as a source layer. The doped semiconductor structure DPS includes at least one doped semiconductor layer. The doped semiconductor layer of the doped semiconductor structure DPS may include n-type impurities or p-type impurities. In an embodiment, the doped semiconductor structure DPS includes at least one of a first conductive doped semiconductor layer including n-type impurities as majority carriers and a second conductive doped semiconductor layer including p-type impurities as majority carriers. The first conductive doped semiconductor layer is a source layer, and the second conductive doped semiconductor layer is a well region. The channel layer 163A of the channel pillar CHP extends into and contacts the source layer of the doped semiconductor structure DPS.

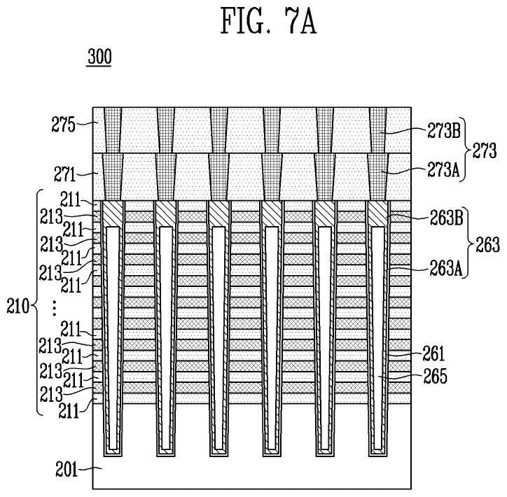

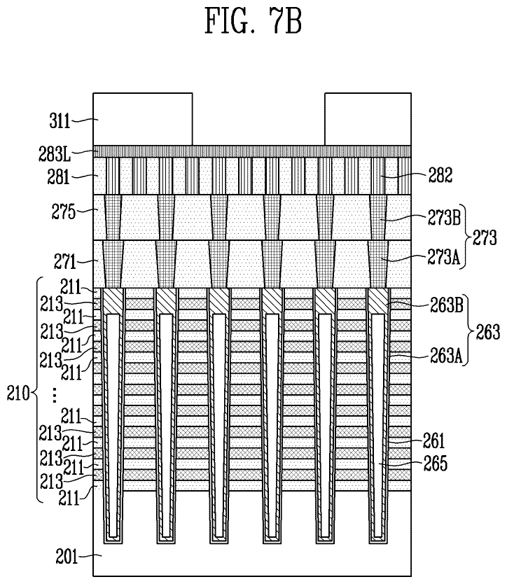

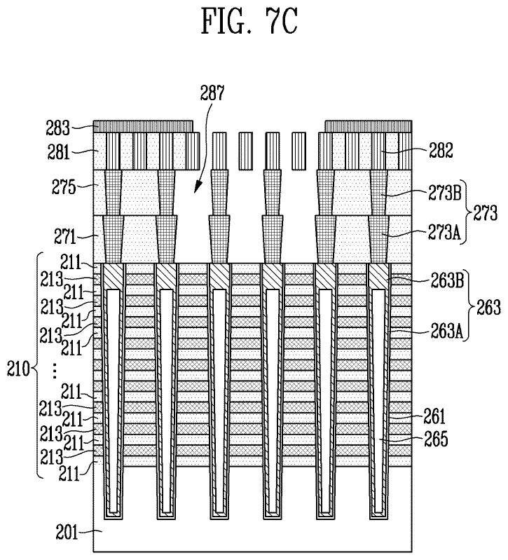

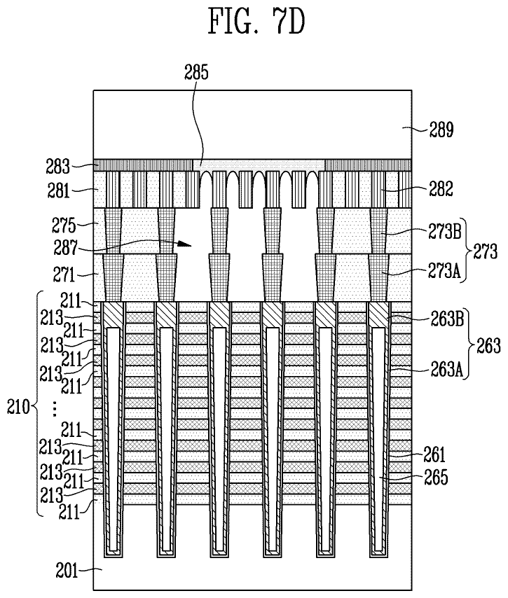

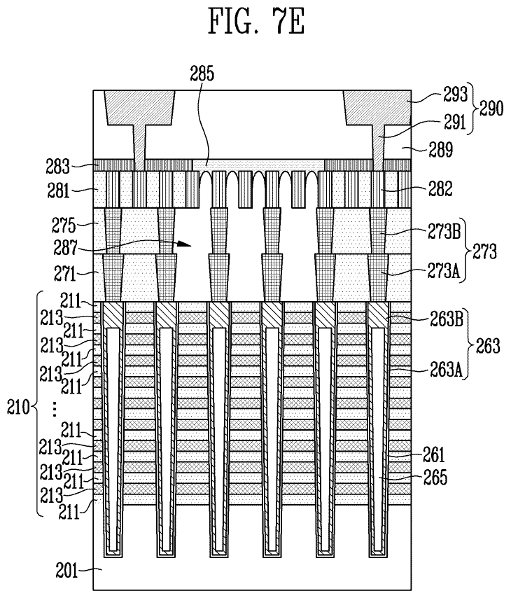

FIG. 7A, FIG. 7B, FIG. 7C, FIG. 7D, and FIG. 7E are cross-sectional views of a semiconductor device formed, before a bonding process, by utilizing a method of manufacturing a semiconductor device according to an embodiment of the present disclosure.

Referring to FIG. 7A, a first structure or a lower structure 300 is formed. The lower structure 300 includes various circuit patterns. The circuit pattern includes passive elements such as a resistor, a capacitor, or the like, a logic circuit including a plurality of transistors, a memory circuit including a plurality of memory cells, or a circuit including a combination of passive elements, logic circuits, and memory circuits. In an embodiment, the lower structure 300 includes a cell array including a memory circuit.

In an embodiment, the cell array includes a sacrificial substrate 201, a stack 210, a plurality of channel pillars 263, a memory layer 261, and a plurality of connection structures 273.

The sacrificial substrate 201 may include a silicon layer.

The stack 210 includes a plurality of interlayer insulating layers 211 alternately stacked with a plurality of gate conductive layers 213 on or over the sacrificial substrate 201. The stack 210 corresponds to the gate stack 160 shown in FIG. 5 in this example. The plurality of interlayer insulating layers 211 may include similar material layers as the plurality of interlayer insulating layers IL as described with reference to FIG. 5, and the plurality of gate conductive layers 213 may include similar material layers as the plurality of the gate conductive layers DSL, WL, and SSL as described with reference to FIG. 5.

The memory layer 261 extends along a sidewall and a bottom surface of each of the plurality of channel pillars 263. In an embodiment, forming each of the plurality of channel pillars 263 and the memory layer 261 includes forming a plurality of openings extending through the stack 210 and extending into the sacrificial substrate 201, forming the memory layer 261 on a surface of the stack adjacent to each opening, and forming a channel pillar 263 within a corresponding opening in the memory layer 261. The memory layer 261 may include similar material layers as the memory layer 161 as described with reference to FIG. 5.

In an embodiment, the process of forming the channel pillar 263 includes forming a channel layer 263A on the memory layer 261 and filling a central region of an opening in the channel layer 263A with a core insulating layer 265 and a capping pattern 263B. The channel layer 263A and the capping pattern 263B may include a semiconductor material such as silicon (Si), germanium (Ge), or a mixture thereof. The capping pattern 263B and a section of the channel layer 263A around the capping pattern 263B may be doped with conductive impurities. The conductive impurities may include n-type impurities, or both n-type impurities and p-type impurities.

Each of the plurality of connection structures 273 is coupled to a corresponding one of the plurality of channel pillars 263, and extends in a stacking direction in which the plurality of interlayer insulating layers 211 and the plurality of gate conductive layers 213 are stacked. Lower insulating layers, 271 and 275 are formed between consecutive connection structures 273. The plurality of connection structures 273 correspond to the plurality of bit line connection structures 173 as described with reference to FIG. 5. In an embodiment, each of the plurality of connection structures 273 includes a first connection structure 273A and a second connection structure 273B. The first connection structure 273A includes a conductive material arranged in the first insulating layer 271 of the lower insulating layer. The second connection structure 273B includes a conductive material arranged in the second insulating layer 275 of the lower insulating layer. The first insulating layer 271 covers the stack 210. Each of the first connection structures 273A contacts a corresponding channel pillar 263 and is electrically coupled to the channel pillar 263. The second insulating layer 275 is arranged over the first insulating layer 271. Each of the second connection structures 273B contacts a corresponding first connection structure 273A and is electrically coupled to the channel pillar 263 via a first connection structure 273A. Each of the first insulating layer 271 and the second insulating layer 275 may include silicon oxide.

Referring to FIG. 7B, a third insulating layer 281 is formed over the lower structure 300 as described with reference to FIG. 7A. The third insulating layer 281 covers the lower structure 300 of FIG. 7A. In an embodiment, the third insulating layer 281 covers the second insulating layer 275 and the plurality of connection structures 273. The third insulating layer 281 may include silicon oxide.

After a plurality of trenches are formed in the third insulating layer 281, each of the plurality of trenches is filled with a conductive material, forming a plurality of wirings 282 extending substantially in parallel. The plurality of wirings 282 corresponds to the plurality of wirings 82 such as described with reference to FIG. 1A, FIG. 1B, and FIG. 1C or the plurality of bit lines BL such as described with reference to FIG. 5 and FIG. 6.

A capping insulating layer 283L covering the plurality of wirings 282 and the third insulating layer 281 is formed. The capping insulating layer 283L may include an insulating material having an etch selectivity relative to the insulating layers 271, 275, and 281. In an embodiment, the capping insulating layer 283L may include silicon nitride.

A mask pattern 311 is formed over the capping insulating layer 283L. In an embodiment, the mask pattern 311 may be a photoresist pattern formed using a photolithography process.

Referring to FIG. 7C, the capping insulating layer 283L of FIG. 7B may be etched by an etch process using the mask pattern 311 of FIG. 7B as an etching barrier, thereby forming a capping insulation pattern 283. The capping insulation pattern 283 corresponds to the mask pattern 311 such as shown in FIG. 7B. After the capping insulation pattern 283 is formed, the mask pattern 311 shown in FIG. 7B is removed.

The capping insulation pattern 283 corresponds to the capping insulation pattern 83 described with reference to FIG. 1A and FIG. 1B or the capping insulation patterns 183 described with reference to FIG. 5. A space between a subset of adjacent wirings 282 is partially covered by the capping insulation pattern 283, and the third insulating layer 281 is partially covered. The capping insulation pattern 283 cover two or more consecutive wirings among the plurality of wirings 282.

Sections of the third insulating layer 281 not covered by the capping insulation pattern 283 is selectively removed. A cavity 287 is formed in a region from which sections of the third insulating layer 281 are removed. By removing sections of the insulating layers 271 and 275 not covered by the capping insulation pattern 283, the cavity 287 is expanded between the plurality of connection structures 273.

Because other sections of the third insulating layer 281 that are covered by the capping insulation pattern 283 partially support the plurality of wirings 282, alignment of the plurality of the wirings 282 may be maintained.

Referring to FIG. 7D, to seal the cavity 287, a sealing insulating layer 285 is formed over the plurality of wirings 282 that are partially exposed. The sealing insulating layer 285 cover a region from which the third insulating layer 281 is removed and may be formed through a chemical vapor deposition method with low step coverage or the like. The sealing insulating layer 285 may include a material capable of preventing metal diffusion. In an embodiment, the sealing insulating layer 285 may include nitrogen doped silicon carbide.

An insulation structure 289 is formed over the sealing insulating layer 285. The insulation structure 289 covers the capping insulation pattern 283. The insulation structure 289 may include a single-layer insulating layer or multiple insulating layers. In an embodiment, the insulation structure 289 may include a Tetra Ethyl Otho Silicate (TEOS) oxide.

Referring to FIG. 7E, a plurality of first conductive structures 290 are formed using a dual damascene process. The dual damascene process may include an etch process that forms a plurality of grooves in which the plurality of first conductive structures 290 are located. Each groove extends through the insulation structure 289 and the capping insulation pattern 283 to a corresponding one of the plurality of wirings 282. Each groove may have a dual damascene structure in which a width of a lower section of the groove is smaller than a width of an upper section of the groove. A lower end of the groove located in the capping insulation pattern 283 is narrower than an upper end of the groove located in the upper region of the insulation structure 289. The lower end of the groove in the capping insulation pattern 283 may have a width corresponding to the width of the corresponding wiring 282. During the etch process that forms the plurality of grooves, the capping insulation pattern 283 functions as an etch stop layer. Though not shown in FIG. 7E, when a central section of the lower end of the groove is aligned with a sidewall of a corresponding wiring 282, a defect where the lower end of the groove is coupled to the cavity 287 may be prevented or reduced because the third insulating layer 281 is protected by the capping insulation pattern 283. Thus, when some of the plurality of first conductive structures 290, formed by filling the plurality of grooves with a conductive material, extend onto the sidewall of the corresponding wiring 282, alignment failure in which one or more of the plurality of first conductive structures 290 extends into the cavity 287 may be reduced or prevented by the third insulating layer 281.

The plurality of first conductive structures 290 correspond to the plurality of conductive structures CST such as described with reference to FIG. 1A and FIG. 1B or the plurality of first conductive bonding structures BS1 as described with reference to FIG. 5. In an embodiment, the plurality of first conductive structures 290 includes a conductive contact plug 291 and a conductive pad pattern 293. Each conductive contact plug 291 contacts a corresponding one of the plurality of wirings 282 and extends between a lower structure including the plurality of connection structures 273 and the conductive pad pattern 293. The conductive pad pattern 293 extends between the conductive contact plug 291 and an upper surface and has a greater width than the corresponding wiring 282.

The conductive contact plug 291 extends through the capping insulation pattern 283 and a lower end of the insulation structure 289, and the conductive pad pattern 293 is located in an upper end of the insulation structures 289.

In an embodiment, the plurality of first conductive structures 290 may function as the plurality of first conductive bonding structures. The plurality of first conductive structures 290 are first conductive bonding structures that are bonded to the plurality of second conductive structures of the circuit. In an embodiment, the circuit includes a peripheral circuit including the plurality of transistors TR such as shown in FIG. 5 and the interconnections 130 such as shown in FIG. 5, and the plurality of second conductive structures include the plurality of second conductive bonding structures BS2 such as shown in FIG. 5.

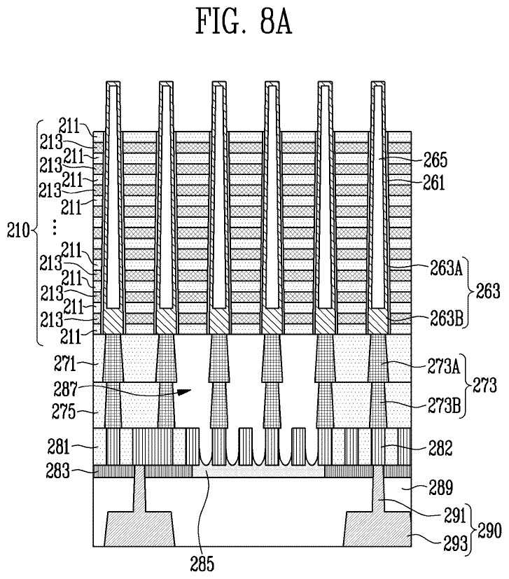

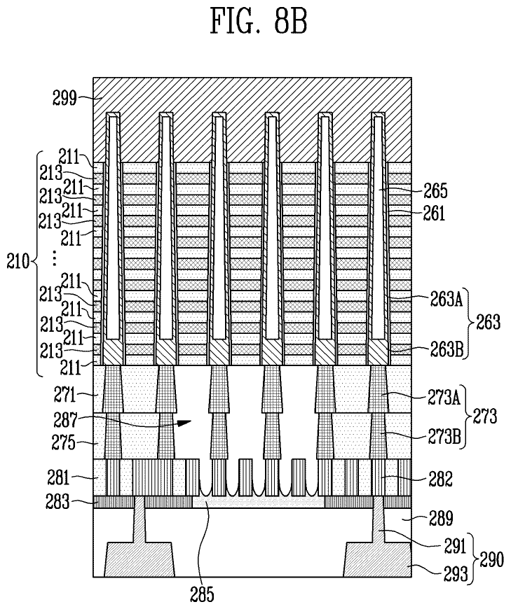

FIG. 8A and FIG. 8B are cross-sectional views of a semiconductor device formed, after the bonding process, by utilizing a method of manufacturing the semiconductor device according to an embodiment of the present disclosure.

Referring to FIG. 8A, after the bonding process, the sacrificial substrate 201 shown in FIG. 7E is removed. A section of the channel layer 263A is exposed by partially removing an exposed section of the memory layer 261.

Referring to FIG. 8B, a doped semiconductor layer 299 covers the exposed section of the channel layer 263A. The doped semiconductor layer 299 forms at least a section of the doped semiconductor structure DPS such as described with reference to FIG. 5.

FIG. 7A, FIG. 7B, FIG. 7C, FIG. 7D, FIG. 7E, FIG. 8A, and FIG. 8B illustrate cross sections of a semiconductor device formed before and after a bonding process based on an embodiment in which the semiconductor device is a semiconductor memory device such as shown in FIG. 5, although the present disclosure is not limited to the semiconductor memory device shown in FIG. 5. For example, embodiments of the present disclosure may be included in various semiconductor devices having circuit structures including the plurality of wirings 82 extending in parallel, and each of the plurality of conductive structures CST is coupled to a corresponding one of the plurality of wirings 82, such as shown in FIG. 1A to FIG. 1C, and the semiconductor device includes the insulating layer 81 and the cavity 87 arranged between the plurality of wirings 82 such as shown in FIG. 1A to FIG. 1C.

According to an embodiment of the present disclosure, by partially arranging an insulating layer having an insulation structure located in a space between wirings such as bit lines, a cavity is formed. The insulating layer may function as a support structure and a bridge failure suppression structure. In an embodiment, operational reliability of a semiconductor memory device may be improved and process defects may be reduced.

Concepts are disclosed in conjunction with examples and embodiments. Those skilled in the art will understand that various modifications, additions, combinations, and substitutions are possible without departing from the scope and technical concepts of the present disclosure. The embodiments disclosed in the present specification should be considered from an illustrative standpoint and not a restrictive standpoint. Therefore, the scope of the present disclosure is not limited to these descriptions. All changes within the meaning and range of equivalency of the claims are included within their scope.

What is claimed is:

1. A semiconductor device comprising:
a plurality of wirings extending in parallel in a first plane and spaced apart by a filled region and an unfilled region between consecutive wirings of the plurality of wirings;
an insulating layer arranged in the filled region;
a conductive pad pattern spaced apart from the plurality of wirings in a first direction perpendicular to the first plane;
a conductive contact plug extending between the conductive pad pattern and a corresponding wiring of the plurality of wirings and contacting the corresponding wiring;
a capping insulation pattern covering the insulating layer and surrounding the conductive contact plug; and
a sealing insulating layer arranged over the plurality of wirings and sealing the unfilled region.

2. The semiconductor device of claim 1, wherein the insulating layer is formed in a bar shape with a width corresponding to a separation distance between the consecutive wirings and a length greater than the width in a direction parallel to the plurality of wirings.

3. The semiconductor device of claim 1, wherein the conductive pad pattern and the conductive contact plug form an integral conductive structure.

4. The semiconductor device of claim 1, wherein each of the conductive pad pattern and the capping insulation pattern has a greater width than the conductive contact plug.

5. The semiconductor device of claim 1, wherein the capping insulation pattern covers a section of the corresponding wiring around the conductive contact plug and covers the consecutive wirings.

6. The semiconductor device of claim 1, wherein the insulating layer has an etch selectivity relative to the capping insulation pattern.

7. The semiconductor device of claim 1, wherein the insulating layer includes silicon oxide; and
wherein the capping insulation pattern includes silicon nitride.

8. A semiconductor device comprising:
a cell array including a plurality of memory cell strings arranged in a plurality of columns in a first plane;
a plurality of bit lines extending in a column direction and coupled to the plurality of columns of the plurality of memory cell strings, the plurality of bit lines spaced apart in a row direction by a filled region and an unfilled region between consecutive bit lines of the plurality of bit lines;
a sealing insulating layer covering a section of each of the consecutive bit lines, the sealing insulating layer sealing the unfilled region, wherein the unfilled region is located between the sealing insulating layer and the cell array;
an insulation structure arranged in the filled region; and
a first conductive bonding structure coupled to a corresponding bit line of the plurality of bit lines and arranged not to overlap the unfilled region in a first direction perpendicular to the first plane.

9. The semiconductor device of claim 8, wherein the cell array comprises:
a plurality of channel pillars of the plurality of memory cell strings;
a plurality of gate conductive layers surrounding the plurality of channel pillars and spaced apart in the vertical direction; and
a memory layer interposed between each of the plurality of gate conductive layers and one of the plurality of channel pillars.

10. The semiconductor device of claim 9, further comprising a plurality of bit line connection structures arranged between the plurality of channel pillars and the plurality of bit lines,
wherein the insulation structure and the unfilled region extend between the consecutive bit lines.

11. The semiconductor device of claim 8, further comprising a capping insulation pattern surrounding an end of the first conductive bonding structure adjacent to the corresponding bit line and covering the insulation structure, and
wherein the sealing insulating layer surrounds the capping insulation pattern.

12. The semiconductor device of claim 11, wherein the insulation structure has an etch selectivity relative to the capping insulation pattern.

13. The semiconductor device of claim 11, wherein the insulation structure includes silicon oxide; and
wherein the capping insulation pattern includes silicon nitride.

14. The semiconductor device of claim 8, wherein the insulation structure comprises a bar-shaped insulating layer having a width corresponding to a separation distance between the plurality of bit lines and a length in a direction parallel to the plurality of bit lines, which length is greater than the width.

15. The semiconductor device of claim 8, wherein the first conductive bonding structure comprises:
a conductive contact plug contacting the corresponding bit line and extending from the cell array; and
a conductive pad pattern extending parallel to the first plane from the conductive contact plug such that the conductive pad pattern has a width greater than a width of the conductive contact plug.

16. The semiconductor device of claim 15, further comprising a capping insulation pattern surrounding an end of the conductive contact plug adjacent to the corresponding bit line and covering the insulation structure;
wherein the capping insulation pattern has a width greater than the width of the conductive contact plug.

17. The semiconductor device of claim 16, wherein the capping insulation pattern covers the consecutive bit lines.

18. The semiconductor device of claim 8, further comprising:
a second conductive bonding structure bonded to the first conductive bonding structure;
an interconnection coupled to the second conductive bonding structure; and
a peripheral circuit including a transistor coupled to the interconnection.

19. A method of manufacturing a semiconductor device, the method comprising:
forming an insulating layer covering a first structure;
forming a plurality of wirings extending through the insulating layer and extending in parallel;
forming a capping insulation pattern over the plurality of wirings and the insulating layer to partially cover a space between consecutive wirings among the plurality of wirings;
removing a section of the insulating layer not covered by the capping insulation pattern;
forming a sealing insulating layer covering a region from which the section of the insulating layer is removed such that a cavity is formed in the region; and
forming a conductive structure passing through the capping insulation pattern and contacting a corresponding wiring of the plurality of wirings.

20. The method of claim 19, wherein forming the first structure comprises:
forming a stack comprising a plurality of interlayer insulating layers alternately stacked with a plurality of gate electrodes;
forming a plurality of channel pillars extending through the stack and surrounded by a memory layer;
forming a plurality of connection structures, each of the plurality of connection structures coupled to a corresponding one of the plurality of channel pillars in a stacking direction of the plurality of interlayer insulating layers and the plurality of gate electrodes; and
forming a first insulating layer between consecutive connection structures of the plurality of connection structures.

21. The method of claim 20, further comprising removing a region of the first insulating layer not covered by the capping insulation pattern;
wherein the cavity extends between consecutive connection structures among the plurality of connection structures.

22. The method of claim 19, wherein forming the conductive structure comprises:
forming a conductive contact plug contacting the corresponding wiring; and
forming a conductive pad pattern contacting the conductive contact plug and having a greater width than the conductive contact plug and the corresponding wiring.

23. The method of claim 19, wherein the capping insulation pattern to covers two or more consecutive wirings among the plurality of wirings.

24. The method of claim 19, wherein the capping insulation pattern has an etch selectivity relative to the insulating layer.

25. The method of claim 19, wherein the insulating layer includes silicon oxide; and
wherein the capping insulation pattern includes silicon nitride.
